(19) United States
(12) Patent Application Publication
(10) Pub. No.: US 2015/0357540 A1
(43) Pub. Date: Dec. 10, 2015

(54) HEAT ENGINE AND METHOD FOR HARVESTING THERMAL ENERGY

(71) Applicants: UNIVERSITY OF ROCHESTER, Rochester, NY (US); UNIVERSITE DE GENEVE, Genève 4 (CH); INSTITUTO DE CIENCIA DE MATERIALES DE MADRID (ICMM-CSIC), Madrid (ES)

(72) Inventors: Andrew N. JORDAN, Rochester, NY (US); Bjorn SOTHMANN, Genève 4 (CH); Markus BÜTTIKER, Genève 4 (CH); Rafael Sánchez RODRIGO, Madrid (ES)

(21) Appl. No.: 14/764,025

(22) PCT Filed: Jan. 29, 2014
(86) PCT No.: PCT/US2014/013694

§ 371 Date: Jul. 28, 2015

Related U.S. Application Data
(60) Provisional application No. 61/757,860, filed on Jan. 29, 2013.
(60) Provisional application No. 61/884,299, filed on Sep. 30, 2013.

(51) Int. Cl. H01L 35/00

(52) U.S. Cl. CPC H01L 35/00

(57) ABSTRACT

In the present disclosure, energy harvesters based on quantum confinement structures, such as resonant quantum wells and/or quantum dots, are described. Also disclosed are methods of harvesting energy utilizing the described energy harvester and methods of manufacturing energy harvesters. Energy harvesting is the process by which energy is taken from the environment and transformed to provide power for electronics.

### CROSS-REFERENCE TO RELATED APPLICATIONS

The present application claims the benefit of the earlier filing date of U.S. Provisional Patent Application No. 61/757,860, filed Jan. 29, 2013, now pending, and 61/884,299, filed Sep. 30, 2013, now pending, the disclosures of both applications are incorporated herein by this reference.

### STATEMENT REGARDING FEDERALLY SPONSORED RESEARCH

This disclosure was made with government support under contract no. DMR-0844899 awarded by the National Science Foundation. The government has certain rights in the disclosure.

### FIELD OF THE DISCLOSURE

The disclosure relates to heat engines, and more particularly to converting heat energy into electric power.

### BACKGROUND OF THE DISCLOSURE

Energy harvesting is the process by which energy is taken from the environment and transformed to provide power for electronics. A wide variety of energy harvesters have been proposed that convert ambient energy to electrical or mechanical power, for example, from vibrations, electromagnetic radiation or by relying on thermoelectric effects. The latter systems turn out to be particularly useful to convert heat on a computer chip back into electrical power, thereby reducing both the power consumption of the chip as well as the need to actively cool it. Unfortunately, present thermoelectric engines have low efficiency. Therefore, an important task in condensed matter physics is to find new ways to harvest ambient thermal energy, particularly at the smallest length scales where electronics operate. Utilizing the physics of mesoscopic electron transport for converting heat to electrical power is a relatively recent endeavor. While the general relationships between electrical and heat currents and their responses to applied voltages and temperature differences are known, the investigation of thermoelectric properties, and in particular the design of nano-engines, has only recently been undertaken. The thermoelectric properties of a mesoscopic one-dimensional wire have been investigated and the best energy filters have been shown to be the best thermoelectrics. The Seebeck effect was investigated for a single quantum dot with a resonant level, and resonant levels were also used as energy filters to make a related heat engine from an adiabatically rocked ratchet. A generalized model has been shown for a static, periodic ratchet, which is a quantum version of the model with state dependent diffusion.

Coulomb-blockaded dots can be ideally efficient converters of heat to work, both in the two-terminal and three-terminal case; however, since transport occurs through multiple tunneling processes, the net current and power is very small. In light of the small currents and power produced by Coulomb-blockaded quantum dots, open cavities with large transmission that weakly changes with incident electron energy have been considered. But, while such an open-cavity system produces more rectified current than Coulomb-blockaded quantum dots, simply increasing the number of quantum channels does not help because the energy dependence of transmissions in typical mesoscopic conductors is a single-channel effect even for a many-channel conductor.

Accordingly, there is a need for nano-scale devices for harvesting energy having higher current and power capabilities.

### BRIEF SUMMARY OF THE DISCLOSURE

In the present disclosure, an energy harvester based on quantum confinement structures, such as resonant quantum wells and/or quantum dots, are described and the operation is described. Also disclosed are methods of harvesting energy utilizing the described energy harvester and methods of manufacturing energy harvesters.

### DESCRIPTION OF THE DRAWINGS

For a fuller understanding of the nature and objects of the disclosure, reference should be made to the following detailed description taken in conjunction with the accompanying drawings, in which:

FIG. 1 is a side cross-section view of a heat engine according to an embodiment of the present disclosure;

FIG. 2A is schematic of an exemplary quantum-dot heat engine in a rectification configuration, according to another embodiment of the present disclosure;

FIG. 2B is a schematic of the quantum dot heat engine of FIG. 2A in a Carnot efficient stopping configuration;

FIG. 3A is a graph of the scaled maximum power of a quantum-dot heat engine according to another embodiment of the present disclosure, the maximum power depicted as a function of ΔE/k_{B}T for ΔT=T and γ and μ_{R} optimized to give maximum power;

FIG. 3B is a graph of the scaled maximum power as a function of ΔT/T for optimized values of E_{R}, γ and μ_{R} of the heat engine of FIG. 3A;

FIG. 3C is a graph of the efficiency at maximum power for the values of E_{R}, γ and μ_{R} chosen to maximize power in the heat engine of FIGS. 3A-3B;

FIG. 3D is a graph of the optimized values plotted versus ΔT/T of the heat engine of FIGS. 3A-3C, where, E_{R}=ΔE/2,μ_{R}=μ/2;

FIG. 4 is a graph depicting a scaled heat current J/(2(k_{B}T)²/h) leaving (blue) or entering (red) the cavity of a quantum-dot heat engine versus temperature difference (x-axis) and applied bias (y-axis) divided by average temperature (the plot is for system parameters optimized for maximal power output, ΔE≈6k_{B}T and γ≈k_{B}T; the dashed curve is the J=0 curve for γ→0 while the solid curve is the J=0 line for the optimized γ); wherein the system can work as a heat engine (HE) in the blue region for ΔT>0,μ_{R}=μ/2>0 (configuration shown in the inset labeled HE), or as a refrigerator (R) in the blue region for ΔT<0,μ_{R}=μ/2<0 (configuration shown in the inset labeled R);

FIG. 5 depicts a self-assembled dot engine according to another embodiment of the present disclosure;

FIG. 6 is a schematic of an operation configuration of a system according to another embodiment of the present disclosure;

FIG. 7A is a graph showing the power per quantum-dot nano-engine plotted against the width of Gaussian random distribution of energy levels (different level widths of the dots, where γₒₚₜ=1.0 2k_{B}T); wherein the power is normalized to the maximum power a single nano-engine can give (for optimized parameters), while the distribution width is plotted in units of ΔE, the average spacing between left and right dot energy levels;

FIG. 7B is a graph showing the power per quantum-dot nano-engine plotted against the width of Gaussian random distribution of energy levels (different applied voltages, where μ_{R,opt}=0.7k_{B}T); wherein the power is normalized to the maximum power a single nano-engine can give (for optimized parameters), while the distribution width is plotted in units of ΔE, the average spacing between left and right dot energy levels;

FIG. 8 is a graph showing the power per quantum-dot nano-engine plotted against the right chemical potential and the average energy difference, ΔE, in units of the optimal power, Pₘₐₓ; wherein the level width is taken to be a sub-optimal value, γ=0.8k_{B}T and the width of Gaussian random distribution is fixed at σ=0.2k_{B}T (the subscript ‘opt’ refers to the parameter that is optimized for maximal power in the clean case);

FIG. 9 is a side cross-sectional view of a heat engine according to another embodiment of the present disclosure;

FIG. 10A is a side cross-sectional view of a quantum-dot heat engine according to another embodiment of the present disclosure;

FIG. 10B is a side cross-sectional view of a quantum-dot heat engine according to another embodiment of the present disclosure;

FIG. 11 is a schematic of a quantum-well based energy harvester according to an embodiment of the present disclosure, wherein a central cavity (red), kept at temperature Tₕ by a hot thermal reservoir (not shown), is connected via quantum wells to two electron reservoirs at temperature T_{c} (blue) (chemical potentials are measured relative to the equilibrium chemical potential);

FIG. 12A is a plot of maximum power in units of

$$\frac{{v}_{2} 𝒜 Γ}{2 ℏ} {( \frac{{k}_{B} Δ T}{2} )}^{2}$$

within linear response as a function of the level positions inside the two quantum wells for a symmetric setup (i.e., a=0);

FIG. 12B is a plot of efficiency at maximum power in units of the Carnot efficiency η_{C} within linear response as a function of the two level positions for a symmetric configuration;

FIG. 12C is a plot of maximum power in units of

$$\frac{{v}_{2} 𝒜 Γ}{2 ℏ} {( \frac{{k}_{B} Δ T}{2} )}^{2}$$

within linear response as a function of the level positions inside the two quantum wells having an asymmetric configuration where a=0.5;

FIG. 12D is a plot of efficiency at maximum power in units of the Carnot efficiency η_{C} within linear response as a function of the two level positions for an asymmetric configuration where a=0.5;

FIG. 13A is a plot, for a quantum-well heat engine, of maximum powerin units of

$$\frac{{v}_{2} 𝒜 Γ}{2 ℏ} {( \frac{{k}_{B} Δ T}{2} )}^{2}$$

within linear response as a function of one level position and the asymmetry of couplings and wherein E_{R}=−10k_{B}T;

FIG. 13B is a plot, for a quantum-well heat engine, of efficiency at maximum power in units of the Carnot efficiency η_{C} within linear response as a function of one level position and the asymmetry of couplings and wherein E_{R}=−10k_{B}T;

FIG. 14A is a plot, for a quantum-well heat engine, of maximal output power (red) and efficiency at maximum power (blue) as a function of temperature difference ΔT/T;

FIG. 14B is a plot, for a quantum-well heat engine, of level position, bias voltage and asymmetry of couplings that maximize the output power as a function of ΔT/T;

FIG. 15 is a flowchart of a method according to an embodiment of the present disclosure;

FIG. 16 is a side view heat engine according to another embodiment of the present disclosure; and

FIG. 17 is a flowchart of a method according to another embodiment of the present disclosure.

### DETAILED DESCRIPTION OF THE DISCLOSURE

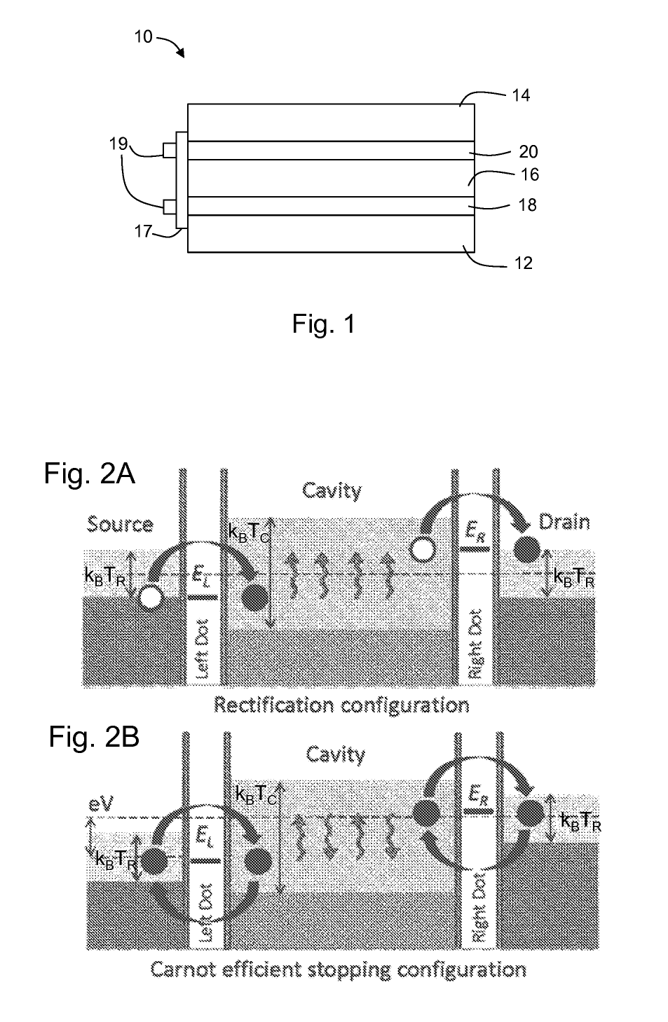

While embodiments of the present disclosure are discussed here with reference to the figures, further details regarding the operation of the device are provided below under the heading “Discussion.” The present disclosure may be embodied as a device 10 for harvesting heat energy (see, e.g., FIG. 1). The device 10 comprises a first electron reservoir 12. The first electron reservoir 12 has a chemical potential (μ_{L}) and a temperature (T_{Res1}). The device 10 comprises a second electron reservoir 14 having a chemical potential (μ_{R}) and a temperature (T_{Res2}) The first and second electron reservoirs 12, 14 are spaced apart from one another. The first electronic reservoir temperature T_{Res1} may be substantially equal to second electron reservoir temperature T_{Res2} (denoted by T_{Res}). In an embodiment, substantially equal temperatures are within 1%, 5%, or 10% of each other. In an exemplary embodiment, the first and second electron reservoirs 12, 14 are electrical leads.

A cavity 16 is generally disposed proximate to the first and second electron reservoirs 12, 14. The cavity 16 may be located between the first and second electron reservoirs 12, 14. The central material 16 has a chemical potential (μ_{Cav}) and a temperature (T_{Cav}) which is greater than the reservoir temperatures (T_{Res}).

A first quantum confinement structure 18 is located such that the first quantum confinement structure 18 forms an electrical connection from the first electron reservoir 12 to the cavity 16. The first quantum confinement structure 18 has an operative energy (E_{L}). A second quantum confinement structure 20 is located such that the second quantum confinement structure 20 forms an electrical connection from the cavity 16 to the second electron reservoir 14. The second quantum confinement structure 20 has an operative energy (E_{R}) which is greater than E_{L} (the operative energy of the first quantum confinement structure 18).

The difference (ΔE) between the second operative energy (E_{R}) and the first operative energy (E_{L}) may be related to an average temperature (T=(T_{Cav}+T_{Res})/2) (or (T=(T_{Cav}+T_{Res1}+T_{Res2})/3)) of the device 10 such that: ΔE≅6k_{B}T, where k_{B} is the Boltzmann constant. In some embodiments, the operative energies (E_{L}, E_{R}) of the first and/or second quantum confinement structures 18, 20 are configurable by providing a corresponding first and/or second gate voltage. In such embodiments, the device 10 comprises one or more gates 19 for applying a gate voltage to corresponding quantum confinement structures. The gate(s) 19 may be arranged in any way known in the art. In some embodiments, the gate 19 is separated from other components of the device 10 by a dielectric 17.

In some embodiments, the device 10 is configured such that a bias voltage is applied between the first electron reservoir 12 and the second electron reservoir 14. For example, the bias voltage V may be such that eV=μ_{L}−μ_{R}.

Devices according to embodiments of the present disclosure may be of various arrangements. For example, FIG. 16 depicts another of the possible arrangements for a device 22 wherein the cavity 16 is disposed at a side of the device 22 and the first and second electron reservoirs 12, 14 are disposed at an opposite side of the device 22 from the cavity 16. As described above, the first quantum confinement structure 18 is disposed between the first electron reservoir 12, and the second quantum confinement structure 20 is disposed between the second electron reservoir 14. In some embodiments, an insulator 24 may be disposed between the electron reservoir/confinement structure combinations.

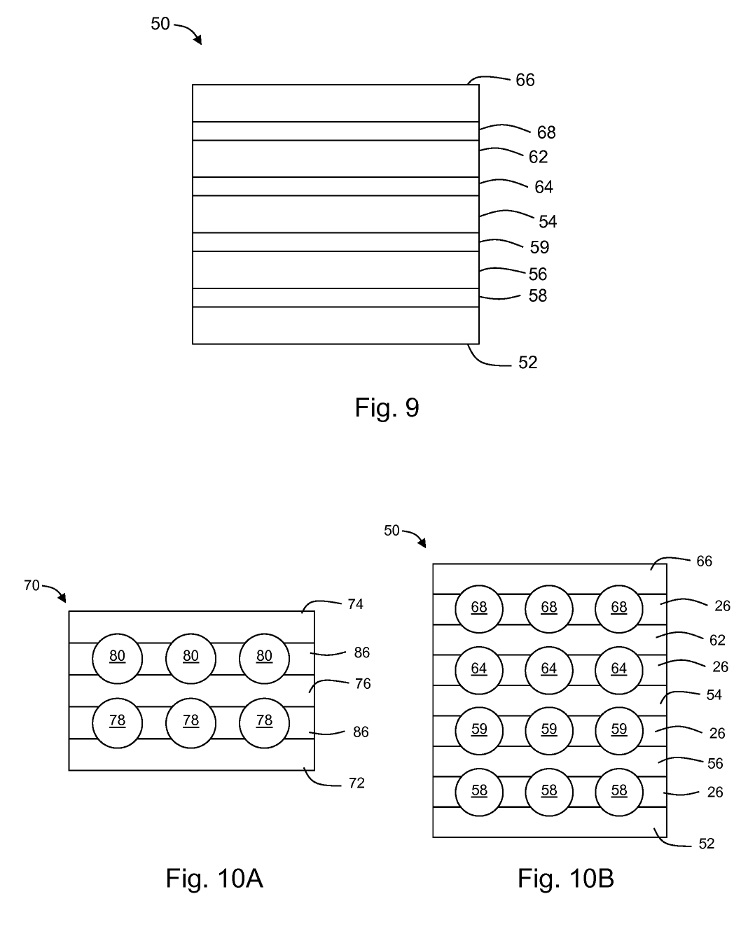

In some embodiments, the structure can be continued in series. As such, rather than a “cold-hot-cold” structure (in keeping with that depicted in device 10), a device could have a “cold-hot-cold-hot . . . -cold” structure, with quantum confinement structures 1, . . . , n between the hot and cold layers, the quantum confinement structures having energies positions E₁, . . . , Eₙ. An example of this is provided as device 50 which may further comprise a second cavity 62 in spaced apart relation to the first and second electron reservoirs 52, 54 and the cavity 56 (see, e.g., FIG. 9). In such embodiments, a third quantum confinement structure 64, having an operative energy (E_{L1}), electrically connects the second electron reservoir 54 to the second cavity 62. The third quantum confinement structure 64 may be configured the same or different from the first quantum confinement structure 58. As such, the operative energy E_{L1} may be equal to E_{L}.

The device 50 further comprises a third electron reservoir 66 having a chemical potential (μ₃) and a temperature (T_{Res3}), the third electron reservoir 66 being in spaced apart relation from the first and second electron reservoirs 52, 54. A fourth quantum confinement structure 68, having an operative energy (E_{R1}), electrically connects the third electron reservoir 66 to the second cavity 62. The fourth quantum confinement structure 68 may be configured the same or different from the second quantum confinement structure 59. As such, the operative energy E_{R1} may be equal to E_{R}. The second cavity 62 has a chemical potential (μ_{Cav2}) and a temperature (T_{Cav2}) which is greater than temperatures (T_{Res2,Res3}) of the second and third electron reservoirs 54, 66. In some embodiments, the chemical potential (μ_{Cav2}) of the second cavity 62 may be the same as the chemical potential (α_{Cav}) of the cavity 56. The relationship of the second cavity chemical potential and the operative energies of the third and fourth quantum confinement structures may be such that: μ_{Cav2}=(E_{L1}+E_{R1})/2.

In some embodiments, the device 70 utilizes quantum confinement structures 78, 80, which are quantum dots (see, e.g., FIG. 10A). In such embodiments, it is useful to refer to the operative energies of the quantum dots as resonant levels (further discussed below). In this way, a first quantum dot 78 is located such that the first quantum dot 78 forms an electrical connection from the first electron reservoir 72 to the cavity 76. The first quantum dot 78 has a resonant level (E_{L}). A second quantum dot 80 is located such that the second quantum dot 80 forms an electrical connection from the cavity 76 to the second electron reservoir 74. The second quantum dot 80 has a resonant level (E_{R}) which is different than E_{L} (the resonant level of the first quantum dot 78). For example, when E_{R}>E_{L}, the device 70 may operate to generate current flow into the second electron reservoir 74.

The device 70 may comprise more than one first quantum dot 78, each connecting the first electron reservoir 72 to the cavity 76. The device 70 may comprise more than one second quantum dot 80, each connecting the cavity 76 to the second electron reservoir 72. In embodiments where the device 70 comprises more than one first and/or second quantum dots 78, 80, the resonant levels of each of the quantum dots may be within the range of, for example, approximately ±10% of the respective resonant level (E_{L} or E_{R}).

The first and second quantum dots 18, 20 may be disposed in insulators 26. The first and second quantum dots 18, 20 have a resonant width (γ). In some embodiments, the resonant width (γ) is approximately equal to k_{B}T. In some embodiments, the approximately equal values may be within 1%, 5%, or 10% of each other. These exemplary relationships are further described below.

In some embodiments, the chemical potential (μ_{Cav}) of the cavity 76 is related to the resonant levels (E_{L}, E_{R}) of the first and second quantum dots 78, 80, such that μ_{Cav}=(E_{L}+E_{R})/2. In some embodiments, the chemical potentials of the first and second electron reservoirs 72, 74 may be such that μ_{L}=−μ/2+(E_{L}+E_{R})/2 and/or μ_{R}=μ2+(E_{L}+E_{R})/2. For example, μ_{L}=−(μ_{L}+μ_{R})/2+(E_{L}+E_{R})/2 and/or μ_{R}=(μ_{L}+μ_{R})/2+(E_{L}+E_{R})/2.

In some embodiments, the device 10 utilizes quantum confinement structures 18, 20, which are quantum wells (see, e.g., FIG. 1). In such embodiments, it is useful to refer to the operative energies of the quantum wells as threshold energies (further discussed below). In this way, a first quantum well 18 is located such that the first quantum well 18 forms an electrical connection from the first electron reservoir 12 to the cavity 16. The first quantum well 18 has a threshold energy (E_{L}). A second quantum well 20 is located such that the second quantum well 20 forms an electrical connection from the cavity 16 to the second electron reservoir 14. The second quantum well 20 has a threshold energy (E_{R}) which is different than E_{L} (the threshold energy of the first quantum well 18). For example, when E_{R}>E_{L}, the device 10 may operate to generate current flow into the second electron reservoir 14.

It should be noted that embodiments of the presently disclosed device may be configured such that the first quantum confinement structure comprises one or more quantum dots, while the second quantum confinement structure is a quantum well. Similarly, the device may be configured such that the first quantum confinement structure is a quantum well, while the second quantum confinement structure comprises one or more quantum dots.

The present disclosure may be embodied as a two-terminal device. For example, a two-terminal energy-harvesting device may comprise:
an electron reservoir having a chemical potential (μ_{Res}) and a temperature (T_{Res});
a cavity having a chemical potential (μ_{Cav}) and a temperature (T_{Cav}) which is greater than temperature (T_{Res}) of the first electron reservoir;
a quantum confinement structure having an operative energy (E), the quantum confinement structure electrically connecting the electron reservoir to the cavity; and
wherein a bias voltage V is applied between the electron reservoir and the cavity.

As disclosed above, the quantum confinement structure of such two-terminal device may be a quantum well or one or more quantum dots.

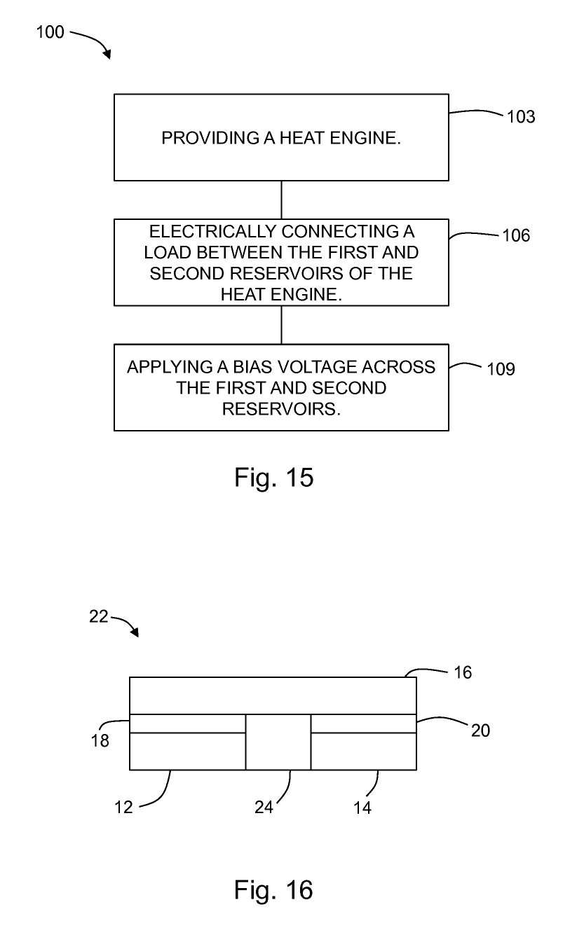

The present disclosure may be embodied as a method 100 of harvesting energy from a substrate having an elevated temperature (see, e.g., FIG. 15). The method 100 comprises the step of providing 103 a heat engine. The provided 103 heat engine may be configured similar to any of the device embodiments described herein. A load is electrically connected 106 between the first and second reservoirs of the provided 103 heat engine. A bias voltage V may be applied 109 across the first and second reservoirs. The applied 109 bias voltage may be, for example, configured such that eV=μ_{L}−μ_{R} (as further described below). In other embodiments, the applied 109 bias voltage is configured such that V=Vₛₜₒₚ/2, where Vₛₜₒₚ is the voltage at which a heat-driven current flowing in a first direction is exactly compensated by a bias-driven current flowing in a second direction opposite to the first direction. The method 100 may further comprise the step of applying 112 a gate voltage to a gate of the provided 103 heat engine.

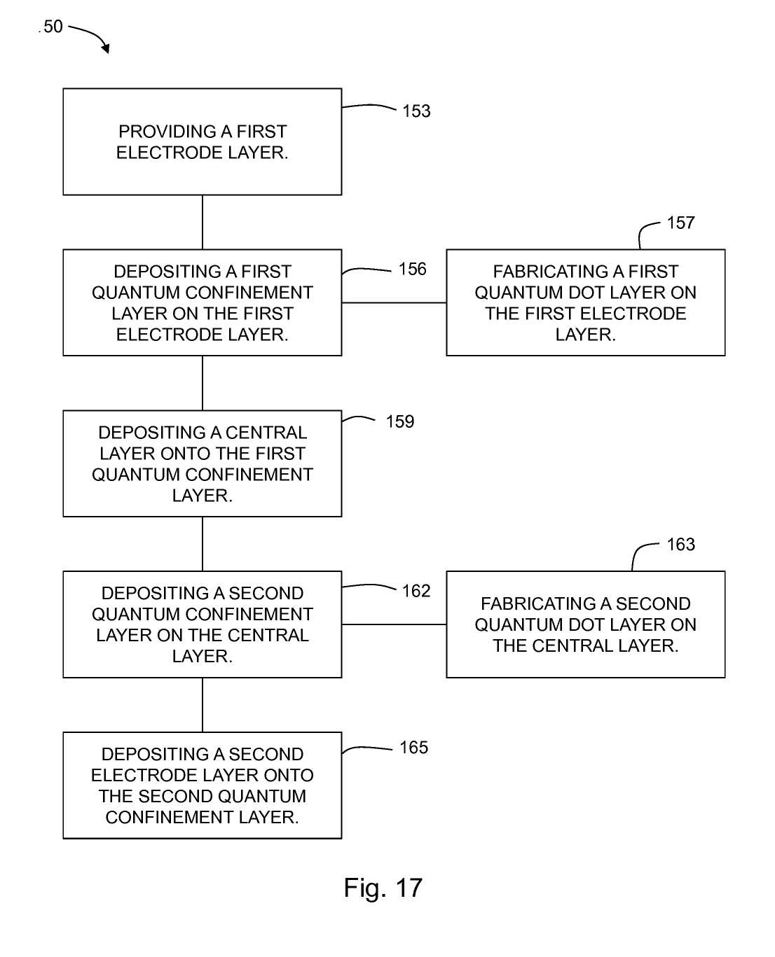

The present disclosure may be embodied as a method 150 of manufacturing a heat engine such as any of the devices discloses herein (see, e.g., FIG. 17). The heat engine may be manufactured for use with a particular device which has a design temperature. In the method 150, a first electrode layer is provided 153. The first electrode layer is of any material suitable to function as a first electron reservoir (e.g., an electrical lead).

A first quantum confinement layer is deposited 156 on the first electrode layer. The deposited 156 first quantum confinement layer is configured such that at least a portion of the layer is in electrical communication with the first electrode layer. The first quantum confinement layer is configured to have an operative energy (E_{L}). The first quantum confinement layer may be, for example, a quantum well layer having a threshold energy (E_{L}).

In other embodiments, the first quantum confinement layer is a layer of one or more quantum dots. As such, the step of depositing 156 the first quantum confinement layer may further comprise the sub-step of fabricating 157 a first quantum dot layer on the first electrode layer. The first quantum dot layer comprises a plurality of quantum dots disposed in an insulating material such that the plurality of quantum dots are not in electrical contact with each other. Each quantum dot is in electrical communication with the first electrode layer. Each quantum dot has a resonant level which is substantially equal to a first resonant level (E_{L}). In some embodiments, the resonant level of each quantum dot of the first quantum dot layer may deviate from the first resonant level E_{L} by a range which may be, for example, approximately ±10% of E_{L}.

A central layer is deposited 159 onto the first quantum confinement layer such that the central layer is in electrical communication with the quantum confinement layer. In embodiments where the first quantum confinement layer comprises a plurality of quantum dots, the central layer is in electrical communication with each quantum dot of the first quantum dot layer. The central layer is deposited 159 such that the central layer is not in electrical communication with the provided 153 first electrode layer except by way of the first quantum confinement layer.

A second quantum confinement layer is deposited 162 on the central layer. The deposited 162 second quantum confinement layer is configured such that at least a portion of the layer is in electrical communication with the central layer. The second quantum confinement layer is configured to have an operative energy (E_{R}). The second quantum confinement layer may be, for example, a quantum well layer having a threshold energy (E_{R}).

In other embodiments, the second quantum confinement layer is a layer of one or more quantum dots. As such, the step of depositing 162 the second quantum confinement layer may further comprise the sub-step of fabricating 163 a second quantum dot layer on the central layer. The second quantum dot layer comprises a plurality of quantum dots disposed in an insulating material such that the plurality of quantum dots are not in electrical contact with each other. Each quantum dot is in electrical communication with the central layer. Each quantum dot has a resonant level which is substantially equal to a second resonant level (E_{R}). In some embodiments, the resonant level of each quantum dot of the second quantum dot layer may deviate from the second resonant level E_{R} by a range which may be, for example, approximately ±10% of E_{R}.

In some embodiments, the central layer is made from a material selected to have a chemical potential (μ_{Cav}) such that μ_{Cav}=(E_{L}+E_{R})/2.

The method 150 further comprises the step of depositing 165 a second electrode layer onto the second quantum confinement layer such that the second electrode layer is in electrical communication with at least a portion of the quantum confinement layer. In embodiments where the second quantum confinement layer comprises a plurality of quantum dots, the second electrode layer is in electrical communication with each quantum dot of the second quantum dot layer. The second electrode layer is deposited 165 such that it is not in electrical communication with the central layer except by way of the second quantum confinement layer.

### Discussion

The following sections are intended to be non-limiting. The assumptions made are for convenience only to show the functionality through mathematics, and are not intended to limit the disclosure.

Discussion of Quantum Dot Exemplary Embodiments

A nano-heat engine utilizes the physics of resonant tunneling in quantum dots in order to transfer electrons only at specific energies. By putting two quantum dots in series with a hot cavity, electrons that enter one lead must gain a prescribed energy in order to exit the opposite lead, transporting a single electron charge. This condition yields an efficient heat engine. Despite the simplicity of the physical model, the optimized rectified current and power is larger than other nano-engines. The ability to scale the power by putting many such engines into a two-dimensional layered structure gives a paradigmatic system for harvesting thermal energy at the nanoscale.

Resonant tunneling is a quantum mechanical effect, where constructive interference permits an electron tunneling through two barriers to have unit transmission. This is only true if the electron has a particular energy equal to the bound state in the quantum dot, or within a range of surrounding energies, whose width is the inverse lifetime of the resonant state. In this way, a resonant tunneling barrier acts like an energy filter. For convenience, the resonant tunnel barrier (or the dot) is assumed to be symmetrically coupled; however, the present disclosure is not intended to be limited to this embodiment.

An exemplary embodiment, depicted in FIGS. 2A-2B, a nano-heat engine is created from a hot cavity connected to cold reservoirs via resonant tunneling quantum dots, each with a resonant level of width γ, and energy E_{L,R}. Solely for convenience, the widths are assumed to be equal, while the energy levels are different (these can be controlled by gate voltages). The nano-cavity to which the dots are connected can be in equilibrium with a heat reservoir of temperature T_{Cav} that is hotter than the first and second electron reservoirs, having chemical potentials μ_{L,R} and equal temperatures, T_{Res}. We assume strong electron-electron and electron-phonon interactions relax the electron energies as they enter and leave the cavity, so the cavity's occupation function may be described with a Fermi function, ƒ(E−μ_{Cav},T_{Cav})=1/(1+exp[(E−μ_{Cav})/k_{B}T_{Cav}]) completely characterized by a cavity chemical potential μ_{Cav} and temperature T_{Cav}, with k_{B} being the Boltzmann constant. This process of inelastic energy mixing is assumed to occur on a faster time scale than the dwell time of an electron in the cavity. Thermal energy flows from the coupled hot bath into the cavity as a heat current, and keeps the temperature different from that of the electron reservoirs. The nature of the heat reservoir is not specified in this example, but refers quite generically to any heat source from which energy is to be harvested.

Thermal broadening of the Fermi functions in the three regions (source, cavity, and drain) is shown by the light shading. FIG. 2A depicts the heat engine in a rectification configuration. In the absence of bias, electrons enter the cavity via the left lead, absorb energy E_{R}−E_{L}, from the cavity, and exit through the right lead, transferring an electrical charge e through the system. FIG. 2B depicts the heat engine in a Carnot efficient stopping configuration (further described below).

The chemical potential of the cavity and its temperature are constrained by conservation of global charge and energy. These constraints are given by the simple equations, I_{L}+I_{R}=0, and J_{L}+J_{R}+J=0 in the steady state, where I_{L,R} is electrical current in the first (e.g., left, as depicted) or second (e.g., right, as depicted) contact, and J_{L,R} the energy current. Energy current is seemingly not conserved because of the heat current J flowing from the hot reservoir.

The currents Iⱼ, Jⱼ=L, R, are given by the well known formula Iⱼ=(2e/h)∫dETⱼ(E)[ƒⱼ−ƒ_{Cav}] and Jⱼ=(2/h)∫dETⱼ(E)E[ƒⱼ−ƒ_{Cav}], where Tⱼ(E) is the transmission function of each contact for each incident electron energy E and h is Planck's constant. In the exemplary quantum dot geometry, the resonant levels give rise to a transmission function of Lorentzian shape, Tⱼ(E)=γ²/[(E−Eⱼ)²+γ²] where γ is the width of the level, or inverse lifetime of an electron in the dot. In the limit where the width of the level is smaller than the thermal energy in cavity/dot system, γ<k_{B} T_{Cav}, k_{B}T_{R}, the transmission will pick out only the energies E_{L} or E_{R} in the above energy integral expressions for the currents giving simple equations. Consequently, the equations for the conservation laws for charge and energy are:

0=ƒ_{L}−ƒ_{CavL}+ƒ_{R}−ƒ_{CavR}, (1)

0=Jh/(2γ)+E_{L}[ƒ_{L}−ƒ_{CavL}]+E_{R}[ƒ_{R}−ƒ_{CavR}], (2)

where ƒ_{L}=ƒ(E_{L}−μ_{L},T_{Res}), ƒ_{R}=ƒ(E_{R}−μ_{R},T_{Res}), ƒ_{CavL}=ƒ(E_{L}−μ_{Cav},T_{Cav}), and ƒ_{CavR}=ƒ(E_{R}−μ_{Cav},T_{Cav}) From equations (1) and (2), one can solve for, for example, the quantity ƒ_{CavR}−ƒ_{R}=Jh/(2γΔE). This quantity is proportional to the electrical current through the right lead I_{L}=−I_{R}≡I, the net current flowing through the system.

A solution of equations (1),(2) to linear order in the deviation of the cavity's temperature and chemical potential from the electronic reservoirs indicates that the maximal power of the heat engine will be produced when the chemical potentials of the reservoirs are symmetrically placed in relation to the average of the resonant levels, μ_{R,L}=±μ/2+(E_{L}+E_{R})/2. For this special case, an exact solution is possible because the constant solution μ_{Cav}=(E_{L}+E_{R})/2 for the cavity chemical potential satisfies the charge conservation condition (1) for all temperatures.

Focusing first on the regime γ<<k_{B}T_{Res},k_{B}T_{Cav}, which can be analyzed analytically, and afterwards discussing the regime γ˜k_{B}T_{Res},k_{B}T_{Cav}, which can be found numerically to yield the largest current and power. Physically, if an electron comes in the left lead at energy E_{L} and exits the right lead with energy E_{R}>E_{L}, it must gain precisely that energy difference. Thus, in the steady state, any incoming energy current J must be associated with an electrical current I, with a conversion factor of the energy difference, ΔE=E_{R}−E_{L}, to the quantum of charge, e,

$$I = \frac{eJ}{Δ E} . \qquad ( 3 )$$

This result holds regardless of what bias is applied or what the temperature is.

The efficiency of the exemplary heat engine, η, is defined as the ratio of the harvested electrical power P=|(μ_{L}−μ_{R})I|/e to the heat current from the hot reservoir, J. For this example it takes a simple form,

$$η = \frac{\vert {μ}_{L} - {μ}_{R} \vert}{Δ E} . \qquad ( 4 )$$

The chemical potential of the cavity and its temperature are found and given in terms of the incoming energy current and chemical potentials and temperature of the electron reservoirs. These are found by employing the principle of conservation of global charge and energy, see Eqs. (1) and (2).

In addition to considering the cavity temperature T_{Cav} as a function of the heat current J being harvested, we can turn our perspective around, and consider where the cavity temperature T_{Cav}, is kept fixed from being in thermal equilibrium with the hot energy source. With this consideration, the heat current J can be expressed in terms of the hot cavity temperature and other system parameters. In the limit where γ<<k_{B}T_{Res},k_{B}T_{Cav},ΔE, we find:

$$J = \frac{2 γΔ E}{h} [ f ( Δ E / 2 , {T}_{Cav} ) - f ( Δ E / 2 - μ / 2 , {T}_{Res} ) ] , \qquad ( 5 )$$

which satisfies charge and energy current conservation. In Eq. (5), h is Planck's constant.

Without bias there is a rectified electrical current given by:

$$I = \frac{eJ}{Δ E} \approx \frac{e γΔ E}{4 h} [ {( {k}_{B} {T}_{Res} )}^{- 1} - {( {k}_{B} {T}_{Cav} )}^{- 1} ] , \qquad ( 6 )$$

in the limit where k_{B}T_{Res},k_{B}T_{Cav}>ΔE. This current is driven solely by the fixed temperature difference between the systems. It is noted that both the heat and electrical current are proportional to γ, the energy width of the resonant level. Consequently, the currents and power produced in this exemplary system will tend to be small since it has been assumed that γ is the smallest energy scale. It is also clear that both are controlled by the size of ΔE, so increasing this energy difference will improve power until it exceeds the temperature. These results are generalized below by numerically optimizing the power produced in this nano-engine.

In order to harvest power from this rectifier, a load may be placed across it. Equivalently, a bias V=μ/e could be applied to this system, tending to reduce the rectified current. At a particular value, μₛₜₒₚ, the rectified current vanishes, giving the maximum load or voltage one could apply to extract electrical power at fixed temperatures T_{Res}, T_{Cav}. This value is found when J and I vanish, given by equation (5):

$${μ}_{stop} = Δ E ( 1 - \frac{{T}_{Res}}{{T}_{Cav}} ) . \qquad ( 7 )$$

Therefore from equation (4), the efficiency is bounded by

$$η \leq 1 - \frac{{T}_{Res}}{{T}_{Cav}} = {η}_{C} .$$

At the stopping voltage, the thermodynamic efficiency attains its theoretical maximum, the Carnot efficiency, η_{C}, showing this system as an ideal nano-heat engine. It should be noted that at this point (see FIG. 2B) the system is reversible with no entropy production. Also noted is the efficiency at the bias point where power is maximum. For temperature larger than ΔE or eV=μ, the Fermi functions can be approximated to find P≈(γ/4hk_{B}T_{Res})μ(μₛₜₒₚ−μ), resulting in a parabola as a function of μ, with maximum power:

$${P}_{max} \approx \frac{γΔ {E}^{2} {η}_{C}^{2}}{16 {hk}_{B} {T}_{Res}} , \qquad ( 8 )$$

and efficiency η_{maxP}=η_{C}/2 which is in agreement with general thermodynamic bounds for systems with time-reversal symmetry.

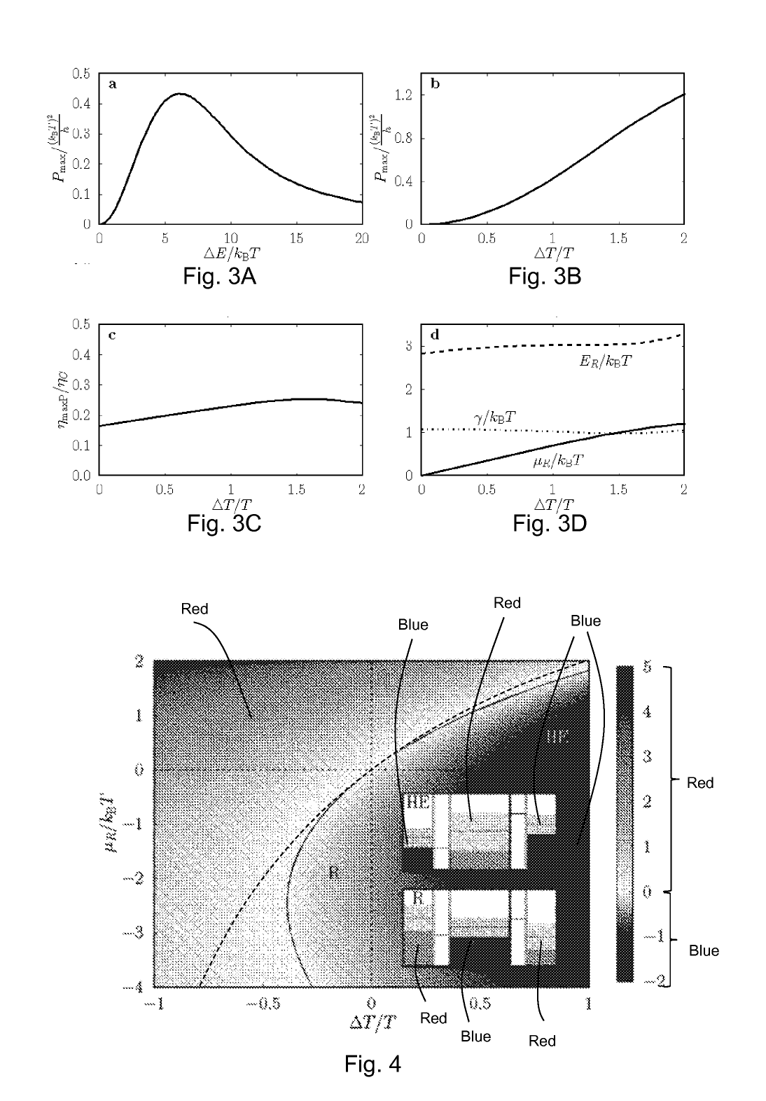

One can go beyond this limit for the efficiency by solving the conservation laws numerically. The total power produced by the heat engine may be optimized by varying the resonance width γ, as well as the energy level difference ΔE and applied bias V=μ/e, given fixed temperatures T_{Res},T_{Cav}. These results are plotted in FIG. 3A, the average temperature T=(T_{Cav}+T_{Res})/2 is defined, as well as its difference, ΔT=T_{Cav}−T_{Res}. FIG. 3B shows that for ΔE<k_{B}T, the power increases as ΔE², as indicated in equation (8), but then levels off and decays exponentially, attaining its maximum around ΔE=6k_{B}T. Similarly, the choice γ=k_{B}T gives optimal power. As such, the power of such a device may be increased (and optimized) by measuring the resonant widths of the quantum dots, and tuning reservoir temperatures and level spacing to the measured resonant widths.

From FIG. 3B, the efficiency at maximum power can be seen to drop from half the Carnot efficiency to about 0.2η_{C}, when the parameters are optimized. However, it is noted that when γ is kept small, in the nonlinear regime, the efficiency can exceed the bound η_{maxP}≦η_{C}/2 found in the linear regime. This small drop in efficiency is more than compensated by the extra power obtained. According to FIGS. 3A-3D, the power reaches a maximum of Pₘₐₓ˜0.4(k_{B}ΔT)²/h, or about 0.1 pW at ΔT=1K, a two order of magnitude increase from a weakly nonlinear cavity. This jump in power can be attributed to the highly efficient conversion of thermal energy into electrical energy by optimizing both the level width and energy level difference. As such, for example, if a 1 cm² square array of these nano-engines were fabricated, each occupying an area of 100 nm², they would produce a power of 0.1 W, operating at ΔT=1K.

In FIG. 4, the heat current J is plotted versus temperature difference and applied bias. There it is shown that when system parameters are optimized to give maximum power, the system can be operated in the mode of a heat engine (HE) or a refrigerator (R). However, in contrast to the case where the levels are narrow compared to the other energy scales (and consequently the cavity can cool to arbitrarily low temperatures in principle, see dashed line, equation (7)), for this choice of parameters the cavity will only cool to the temperature where the J=0 curve (solid line) bends back.

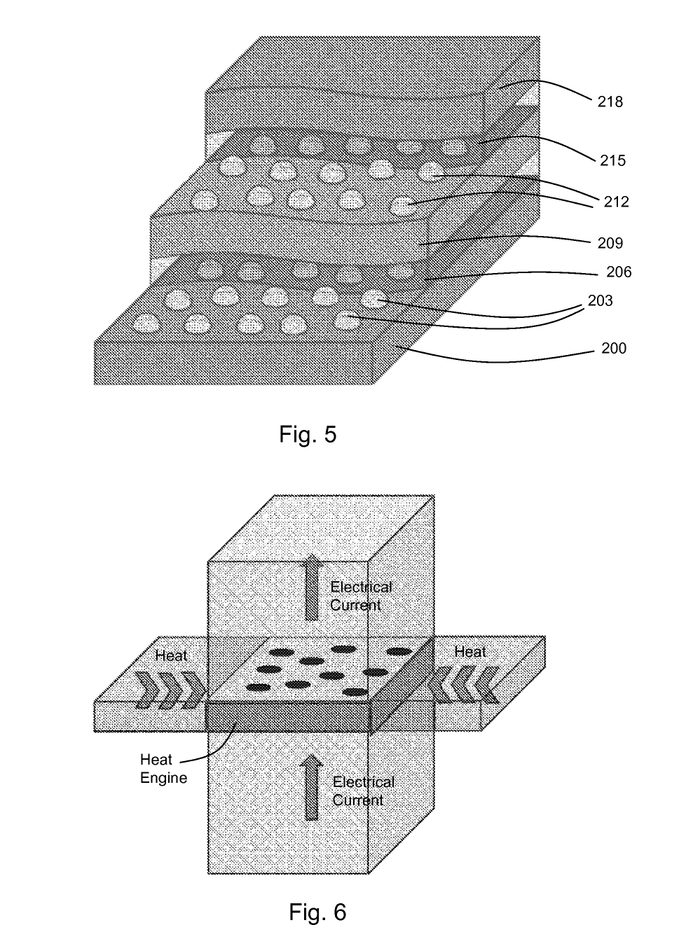

There will be other quantum dot resonant levels the electron can occupy that are higher up in energy. The cavity temperature and applied bias have been assumed to be sufficiently small such that transport through these levels can be neglected. This exemplary embodiment is quite general, so it may be applied to both semiconductor dots in two-dimensional electron gases, as well as three dimensional metallic dots. In this latter case, one can fabricate an entire plane of repeated nano-engines in parallel in order to scale the power. Furthering this idea, for such a repeated array of cavities and quantum dots, one can connect all the cavities to make a single engine (see, e.g., FIG. 5). The two boundary layers comprise planes of quantum dots, so electrons can only penetrate through them. These layers sandwich a hot interior region and separate it from the left and right cold exterior contacts. This is equivalent to taking a large cavity with two leads and scaling the power by adding more quantum dots (rather than trying to add more channels to a single contact). The sandwich engine fabricated with self-assembled quantum dots tolerates variations in width and fluctuations in energy levels.

FIG. 5 depicts such a self-assembled dot engine; wherein a cold bottom electrode (200) is covered with a layer of quantum dots (203) embedded in an insulating matrix (206). The quantum dot layer is covered by the hot central region (209). On top of it, there is another quantum dot layer (212) and another insulating matrix layer (215). The whole structure is terminated by a cold top electrode (218). The positions of the quantum dots in the two layers do not have to match each other. Thus, the device can be realized using self-assembled quantum dots. The latter can have charging energies and single-particle level spacings of the order of 10 meV, thereby allowing the nano-engine to operate at room temperature.

The basic operating configuration for the engine is shown in FIG. 6. Heat flows into the engine from the hot energy source from which energy is to be harvested, and the heat is converted into electrical power, along with residual thermal energy, and dumped into the cold temperature bath. The electrical current is carried by the cold thermal bath, where it powers a load and then completes the electrical circuit on the opposite cold terminal. The flow of heat out of the hot energy source will consequently tend to cool the hot source. One application of such an energy harvesting device is taking heat away from computer chips and running other devices on the chip itself. In electrical chips, thermal energy is an abundant and free resource. Indeed, heat is not only free, it is a nuisance preventing further improvements on chip technology. The ability of the proposed heat engine to not only harvest thermal energy, converting some of it into electrical power, but also to cool the hot source is a side benefit to the proposal of including such heat-engines as part of an emerging chip technology.

FIG. 6 is a schematic of the system operation configuration. Heat enters the engine from the pink hot region, indicated by the chevrons from the left and right of the schematic. The engine itself is signified by the central region with black holes indicating the position of the resonant tunneling quantum dots. The position of the holes can be ordered or disordered. Electrical current is generated perpendicular to the layers, indicated with the arrows flowing from the bottom to the top of the schematic, in the cold regions.

In the actual fabrication of a resonant tunneling nano-engine, as long as there are only a few dots, the precise placement of the resonant levels can be controlled by gate voltages in order to maximize the power generated by the engine. However, such control may not be practical with self-assembled quantum dots with charging energies and single-particle level spacings of the order of 10 meV (thereby allowing the nano-engine to operate at room temperature). To make such an engine, there are several possible fabrications techniques that could be employed using layers of quantum dots and wells to have the resonant energy levels lower than the Fermi energy on one side of the heat source, and higher on the other side. However, in these fabrication methods, the growth of quantum dots does not typically occur at a perfectly regular rate, so there will likely be variation of the resonant energy level from dot to dot.

Degradation of the performance of a heat engine due to such variation may be evaluated considering the energy-resolved current arising from a number of electrons passing through N quantum dots on the left and then the right layer. The total current coming from the left slice is given by:

$${I}_{L}^{tot} = \frac{2 e}{h} \int d {ET}_{eff , L} [ f ( E - {μ}_{L} , {T}_{Res} ) - f ( E - {μ}_{Cav} , {T}_{Cav} ) ] {T}_{eff , L} = {\sum }_{i = 1}^{N} {T}_{i} ( E , {E}_{i} ) , \qquad ( 9 )$$

with similar equations for the total right current, as well as the energy currents. Here, Tᵢ(E, Eᵢ) is the transmission probability of quantum dot i, which has a resonant energy level Eᵢ and a width γᵢ, Tᵢ(E,Eᵢ)=γᵢ²/[(E−Eᵢ)²+γᵢ²] for symmetrically coupled quantum dots. Since neither the left nor cavity Fermi functions depend on the level placement, the sum over the quantum dots can be done to give an effective transmission function T_{eff,L}, for the whole left slice. For convenience, the fabrication process is assumed to be a Gaussian random one, where the energy level Eᵢ is a random variable with an average of E_{L}, and a standard deviation of σ. Additionally, only random variation in Eᵢ is considered below, but there will also be variation in γᵢ, which is ignored for convenience. With this model, the effective transmission will have the average value:

[symbol]

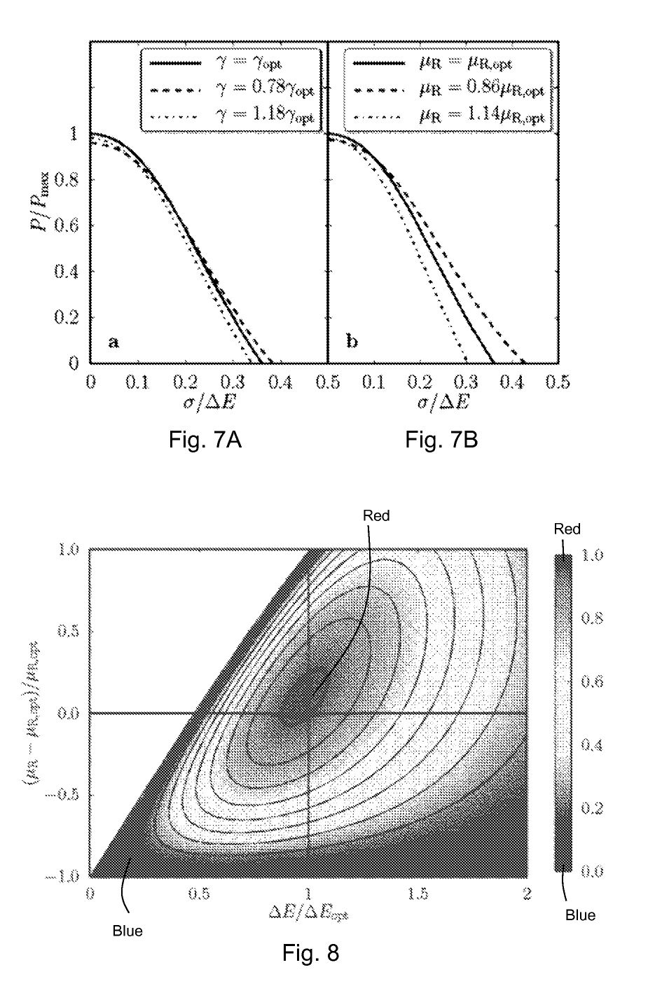

T_{eff,L} [symbol] =N [symbol] Tᵢ(E,Ē) [symbol] ₚ=N∫dĒT(E−Ē)P_{G}( E̅,σ), (10)

where P_{G} is the Gaussian distribution described above. Thus, the effective transmission function is shown as simply a convolution of the Lorentzian transmission function and the Gaussian distribution, known as a Voigt profile. This leads to further broadening of the Lorentzian width. With these considerations, the conservation laws for charge and energy retain the same basic form as described above, but with N times the Voigt profile playing the role of the energy-dependent transmission for the left and right leads. These equations have been numerically solved and the maximum power per nano-engine is plotted versus the width of the Gaussian distribution in FIG. 7A-7B. The parameters are chosen so as to optimize the engine's performance without randomness in the level position. As the randomness of the level position is increased, the power begins to drop as expected. However, even when the scatter of the energy levels is 10% of ΔE, the power only drops to 90% of its maximum, showing that this engine is robust to these kinds of fluctuations in fabrication. Notice that if the level width is less than the optimal amount, some disorder in the level energy can actually improve performance in comparison to a cleanly optimized level width. This is because of the additional broadening in energy space the level disorder provides. Another interesting effect is shown in FIG. 8, where the value of γ is not optimal together with a given amount of disorder in the energy level positions. The figure demonstrates that even in this experimentally realistic case, a change of the voltage and relative level spacing can yield results which are nearly as good as the optimal case.

Discussion of Quantum Well Exemplary Embodiments

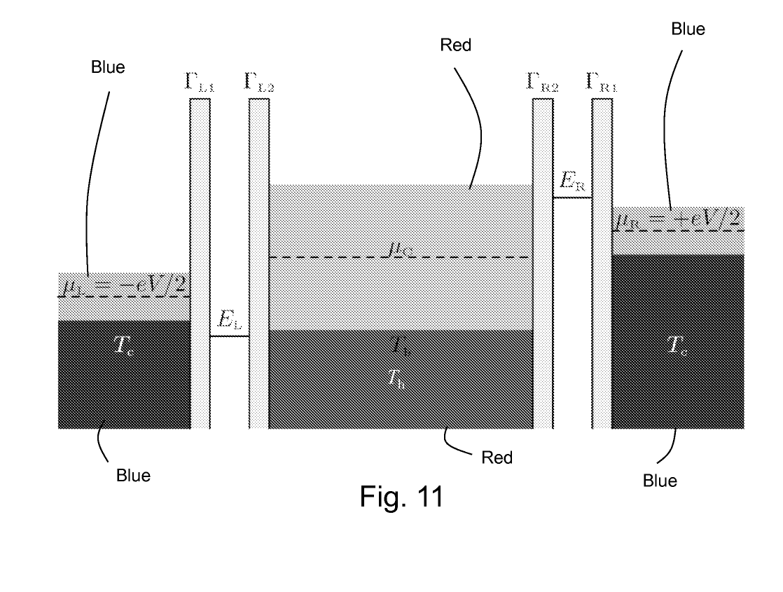

An exemplary embodiment of the present disclosure using quantum wells is schematically shown in FIG. 11. The device comprises a central cavity connected via quantum wells to two electronic reservoirs. In the following, the quantum wells are assumed to be non-interacting such that charging effects can be neglected in a simplified model.

The electronic reservoirs, r=L, R, are characterized by a Fermi function ƒᵣ(E)={exp[E−μᵣ)/(k_{B}T_{Res})]+1}⁻¹ with temperature T_{Res} and chemical potentials μᵣ. The cavity is assumed to be in thermal equilibrium with a heat bath of temperature T_{Cav}. The heat bath can be of any type and depends on the source from which energy will be harvested. Strong electron-phonon and electron-electron interactions within the cavity relax the energy of the electrons entering and leaving the cavity towards a Fermi distribution ƒ_{Cav} (E)={exp[E−μ_{Cav})/(k_{B}T_{Cav})]+1}⁻¹ characterized by the cavity temperature T_{Cav} and the cavity's chemical potential μ_{Cav}.

The cavity potential μ_{Cav} as well as its temperature T_{Cav} (or, equivalently, the heat current J injected from the heat bath into the cavity to keep the heat bath at a given temperature T_{Cav}) are determined from the conservation of charge and energy, I_{L}+I_{R}=0 and J_{L}^{E}+J_{R}^{E}+J=0. Here, I^{r} denotes the current flowing from reservoir r into the cavity. Similarly, Jᵣ^{E} denotes the energy current flowing from reservoir r into the cavity.

The charge and energy currents can be evaluated within a scattering matrix approach as:

$${I}_{r} = \frac{{ev}_{2} 𝒜}{2 πℏ} \int d {E}_{⊥} d {E}_{z} {T}_{Res} ( {E}_{z} ) [ {f}_{r} ( {E}_{z} + {E}_{⊥} ) - {f}_{Cav} ( {E}_{z} + {E}_{⊥} ) ] \qquad ( 11 )$$

### And:

$${J}_{r}^{E} = \frac{{v}_{2} 𝒜}{2 πℏ} \int d {E}_{⊥} d {E}_{z} ( {E}_{z} + {E}_{⊥} ) {T}_{Res} ( {E}_{z} ) [ {f}_{r} ( {E}_{z} + {E}_{⊥} ) - {f}_{Cav} ( {E}_{z} + {E}_{⊥} ) ] . \qquad ( 12 )$$

Here, v₂=m_{*}/(πh²) is the density of states of the two-dimensional electron gas inside the quantum well with the effective electron mass m_{*}. A denotes the surface area of the well. E_{z} and E_{⊥} are the energy associated with motion in the well's plane and perpendicular to it, respectively. The transmission of quantum well r is given by:

$${T}_{r} ( E ) = \frac{{Γ}_{r 1} ( E ) {Γ}_{r 2} ( E )}{{( E - {E}_{nr} )}^{2} + {[ {Γ}_{r 1} ( E ) + {Γ}_{r 2} ( E ) ]}^{2} / 4} . \qquad ( 13 )$$

Here, Γᵣ₁(E) and Γᵣ₂(E) denote the (energy-dependent) coupling strength of the quantum well to the electronic reservoir r and the cavity, respectively. The energies of the resonant levels (more precisely the subband thresholds) within the quantum well are given by Eₙᵣ. For a parallel geometry with well width L, the resonant levels are given by the discrete eigenenergies of a particle in a box, Eₙᵣ=(πhn)²/(2m*L²).

In the following, the analysis is restricted to the situation of weak couplings, Γᵣ₁Γᵣ₂<<k_{B}T_{Res},k_{B}T_{Cav}, whose energy dependence can be neglected. Furthermore, the level spacing inside the quantum wells is assumed to be large such that only the lowest energy state is relevant for transport. In this case, the transmission function reduces to a single delta peak, Tᵣ(E)=2πΓ₁ᵣΓ₂ᵣ/Γ₁ᵣ+Γ₂ᵣδ(E_{z}−E₁ᵣ). This allows the integrals in expressions (11) and (12) to be analytically solved for the currents and yields:

$${I}_{r} = \frac{{ev}_{2} 𝒜}{ℏ} \frac{{Γ}_{r 1} {Γ}_{r 2}}{{Γ}_{r 1} + {Γ}_{r 2}} [ {k}_{B} {T}_{Res} {K}_{1} ( \frac{{μ}_{r} - {E}_{r}}{{k}_{B} {T}_{Res}} ) - {k}_{B} {T}_{Cav} {K}_{1} ( \frac{{μ}_{Cav} - {E}_{r}}{{k}_{B} {T}_{Cav}} ) ] , \qquad ( 14 )$$

as well as:

$${J}_{r}^{E} = \frac{{E}_{r}}{e} {I}_{r} + \frac{{v}_{2} 𝒜}{ℏ} \frac{{Γ}_{r 1} {Γ}_{r 2}}{{Γ}_{r 1} + {Γ}_{r 2}} [ {( {k}_{B} {T}_{Res} )}^{2} {K}_{2} ( \frac{{μ}_{r} - {E}_{r}}{{k}_{B} {T}_{Res}} ) - {( {k}_{B} {T}_{Cav} )}^{2} {K}_{2} ( \frac{{μ}_{Cav} - {E}_{r}}{{k}_{B} {T}_{Cav}} ) ] , \qquad ( 15 )$$

where, for simplicity, the energy of the single resonant level in the quantum wells is denoted as Eᵣ. Furthermore, the integrals K₁(x)=∫₀^{∞}dt(1+e^{t-x})⁻¹=log(1+e^{x}) and K₂(x)=∫₀^{∞}dt t(1+e^{t-x})⁻¹=Li₂(−e^{x}) are introduced with the dilogarithm

$${Li}_{2} ( z ) = {\sum }_{k = 1}^{∞} \frac{{z}^{k}}{{k}^{2}} .$$

The heat current is made up from two different contributions. While the first one is simply proportional to the charge current, the second term breaks this proportionality. It is noted that in the case of quantum dots with sharp levels, the latter term is absent.

In the following, the system in the linear-response regime is analyzed first and the nonlinear situation is subsequently analyzed. It is assumed that both quantum wells are intrinsically symmetric, i.e., ΓL₁=Γ_{L2} ≡(1+a)Γ, Γ_{R1}=Γ_{R2}≡(1−a)Γ. Here, Γ denotes the total coupling strength whereas −1≦a≦1 characterizes the asymmetry between the coupling of the left and the right well.

Linear-Response Regime

The analysis begins with a discussion of the linear-response regime. To simplify notation, the average temperature T=(T_{Cav}+T_{Res})/2 and the temperature difference ΔT=T_{Cav}−T_{Res} are used. To linear order in the temperature difference ΔT and the bias voltage eV=μ_{R}−μ_{L} applied between the two electronic reservoirs, the charge current through the system is given by:

$$\begin{matrix}{I}_{L} = - {I}_{R} \\ = \frac{e {v}_{2} 𝒜 Γ}{2 ℏ} {g}_{1} ( \frac{{E}_{L}}{{k}_{B} T} , \frac{{E}_{R}}{{k}_{B} T} ) [ - eV - {k}_{B} Δ T {g}_{2} ( \frac{{E}_{L}}{{k}_{B} T} , \frac{{E}_{R}}{{k}_{B} T} ) ] ,\end{matrix} \qquad ( 16 )$$

with the auxiliary functions:

$${g}_{1} ( x , y ) = \frac{1 - {a}^{2}}{2 + ( 1 - a ) {e}^{x} + ( 1 + a ) {e}^{y}} \qquad ( 17 )$$

and

g₂(x,y)=x−y+(1+e^{x})log(1−e^{-x})−(1+e^{y})log(1+e^{-y}) (18)

At V=0, a finite current driven by ΔT≠0 flows in a direction that depends on the position of the resonant levels. If, for example, E_{R}>E_{L}, electrons will be transferred from the left to the right lead.

The power delivered by the heat-driven current against the externally applied bias voltage V is simply given by P=I_{L}V. It vanishes at zero applied voltage. Furthermore, it also vanishes at the so called stopping voltage Vₛₜₒₚ where the heat-driven current is exactly compensated by the bias-driven current flowing in the opposite direction. In between these two extreme cases, the output power depends quadratically on the bias voltage and takes its maximal value at half the stopping voltage. Here, the maximal output power is given by:

$${P}_{max} = \frac{{v}_{2} 𝒜 Γ}{2 ℏ} {( \frac{{k}_{B} Δ T}{2} )}^{2} {g}_{1} ( \frac{{E}_{L}}{{k}_{B} T} , \frac{{E}_{R}}{{k}_{B} T} ) {g}_{2}^{2} ( \frac{{E}_{L}}{{k}_{B} T} , \frac{{E}_{R}}{{k}_{B} T} ) \qquad ( 19 )$$

The efficiency η of the quantum-well heat engine is defined as the ratio between the output power and the input heat. The latter is given by the heat current J injected from the heat bath, i.e., we have η=P/J. For a bias voltage V=Vₛₜₒₚ/2 that delivers the maximal output power, the heat current is given by:

$$J = \frac{{v}_{2} 𝒜 Γ}{2 ℏ} {( {k}_{B} T )}^{2} \frac{Δ T}{T} {g}_{3} ( \frac{{E}_{L}}{{k}_{B} T} , \frac{{E}_{R}}{{k}_{B} T} ) , \qquad ( 20 )$$

where the function g₃ (x,y) that satisfies 0<g₃ (x,y)<2π²/3 is given by:

$${g}_{3} ( x , y ) = \frac{2 {π}^{2}}{3} - \frac{1}{2} ( x - y ) {g}_{1} ( x , y ) [ x - y - 2 {g}_{2} ( x , y ) ] - 2 ( 1 + a ) {Li}_{2} ( \frac{1}{1 + {e}^{- x}} ) - 2 ( 1 - a ) {Li}_{2} ( \frac{1}{1 + {e}^{- y}} ) - 2 ( 1 + a ) log ( 1 + {e}^{x} ) log ( 1 + {e}^{- x} ) - 2 ( 1 - a ) log ( 1 + {e}^{y} ) log ( 1 + {e}^{- y} ) - {g}_{1} ( x , y ) ( 1 + {e}^{x} ) ( 1 + {e}^{y} ) log ( 1 + {e}^{- x} ) \times log ( 1 + {e}^{- y} ) - {g}_{1} ( x , y ) {log}^{2} ( 1 + {e}^{- x} ) [ {e}^{x} sinh x + \frac{1 + a}{1 - a} {e}^{x} ( 1 + {e}^{y} ) ] - {g}_{1} ( x , y ) {log}^{2} ( 1 + {e}^{- y} ) [ {e}^{y} sinh y \frac{1 + a}{1 - a} {e}^{y} ( 1 + {e}^{x} ) ] . \qquad ( 21 )$$

Hence, the efficiency at maximum power is simply given by:

$${η}_{max P} = \frac{{η}_{C}}{4} \frac{{g}_{1} ( \frac{{E}_{L}}{{k}_{B} T} , \frac{{E}_{R}}{{k}_{B} T} ) {g}_{2}^{2} ( \frac{{E}_{L}}{{k}_{B} T} , \frac{{E}_{R}}{{k}_{B} T} )}{{g}_{3} ( \frac{{E}_{L}}{{k}_{B} T} , \frac{{E}_{R}}{{k}_{B} T} )} , \qquad ( 22 )$$

with the Carnot efficiency

$${η}_{C} = 1 - \frac{{T}_{Res}}{{T}_{Ca v}} \approx \frac{Δ T}{T} .$$

Discussion of Symmetric System, a=0

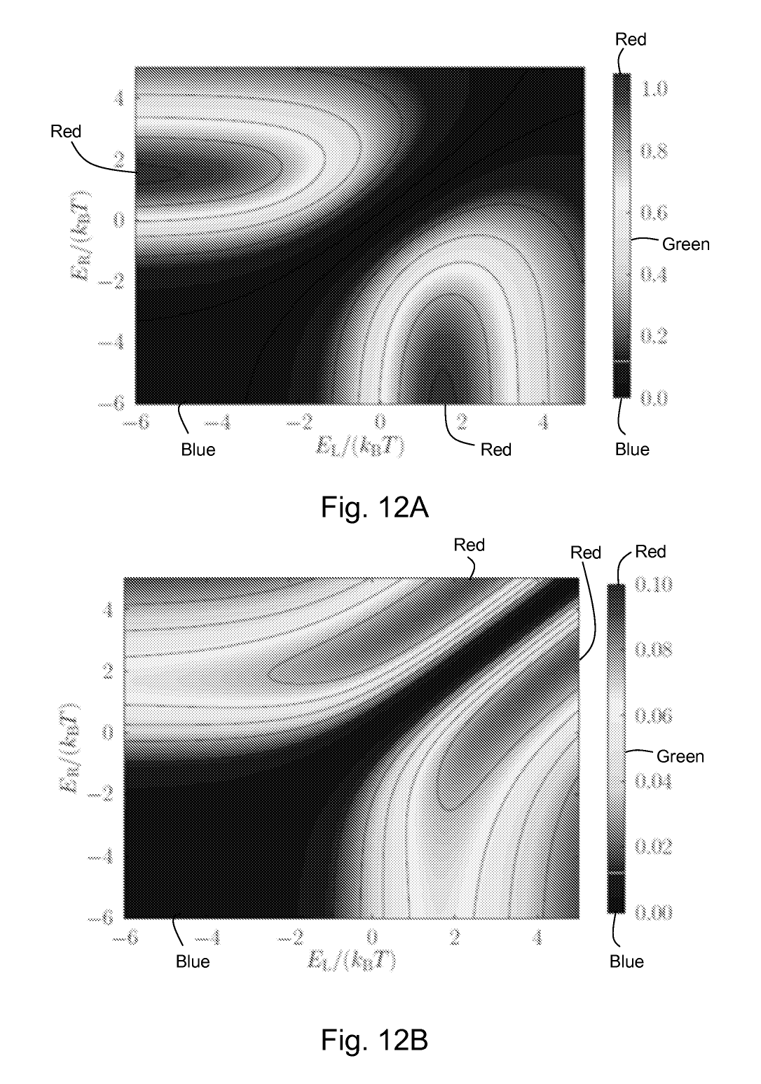

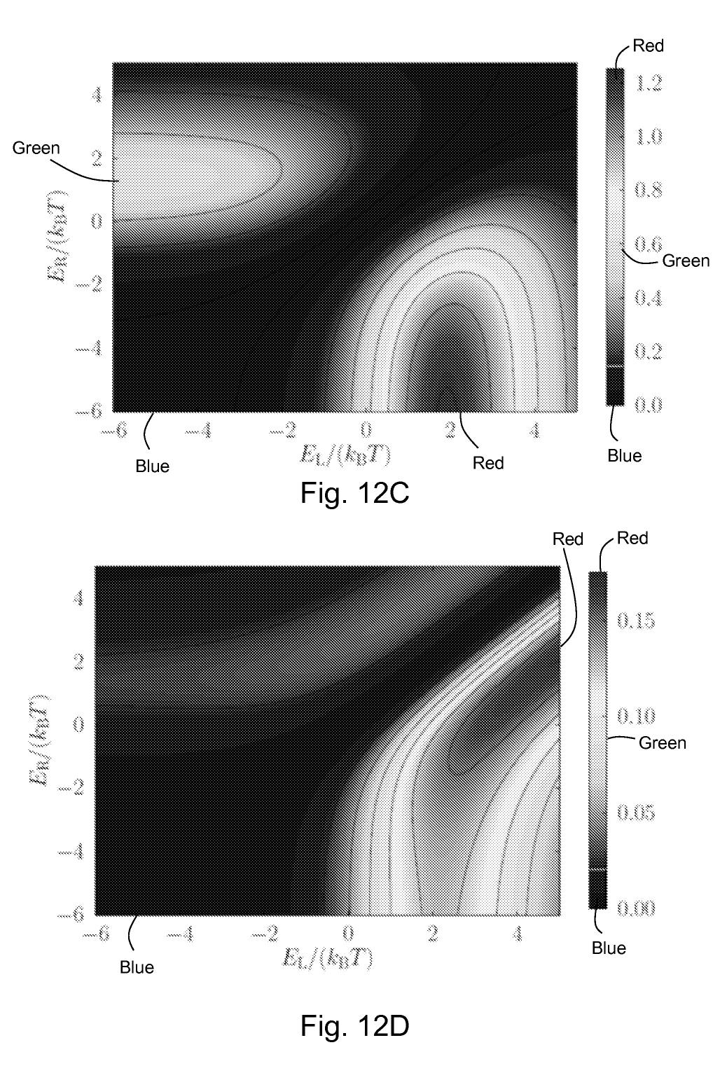

The output power and the efficiency are discussed here in more detail, first focusing on a symmetric system, a=0. FIGS. 12A-12D show the power as a function of the level positions E_{L} and E_{R}. It is symmetric with respect to an exchange of E_{L} and E_{R}. The maximal output power of approximately

$${P}_{max} \approx \frac{{v}_{2} 𝒜 Γ}{2 ℏ} {( \frac{{k}_{B} Δ T}{2} )}^{2}$$

arises when one of the two levels is deep below the equilibrium chemical potential, −E_{L/R}>>k_{B}T while the other level is located at about E_{L/R}≈1.5k_{B}T. An explanation for this will be given below.

Similarly to the power, the efficiency is also symmetric under an exchange of the level positions. It takes its maximal value of η≈0.1η_{C} in the region E_{L},E_{R}>0 where the output power is strongly suppressed. For these parameters, energy filtering is efficient but the number of electrons that can pass through the filter is exponentially suppressed. For level positions that maximize the output power, the efficiency is slightly reduced to η≈0.07η_{C}. This efficiency is much smaller than the efficiency at maximum power of a quantum-dot heat engine with couplings small compared to temperature. The latter lets only electrons of a specific energy pass through the quantum dot. Hence, charge and heat currents are proportional to each other. In such a tight-coupling limit, the efficiency at maximum power in the linear-response regime is given by η_{C}/2. In contrast, the quantum wells transmit electrons of any energy larger than the level position, because any energy larger than the ground state energy can be expressed as E_{⊥}+E_{z}, where E_{z} is the z-component and E_{⊥} the perpendicular component of the electron's kinetic energy. Consequently, even high-energy electrons can traverse the barrier, provided most of the energy is in the perpendicular degrees of freedom, and E_{z} matches the resonant energy. Therefore, quantum wells are much less efficient energy filters than quantum dots.

With regard to why the quantum-well heat engine is about a factor of three less than the efficiency of a quantum-dot heat engine with level width of the order of k_{B}T, the schematic of FIG. 11 is analyzed. The right quantum well acts as an efficient energy filter because the number of electrons larger than E_{R} is exponentially small. The energy filtering at the left quantum well relies on a different mechanism. In order for an electron of energy E to enter the cavity, the engine requires ƒ_{L}(E)>0 such that the reservoir state is occupied. At the same time, ƒ_{Cav}(E)<1 is also required such that a free state is available in the cavity. These conditions define an energy window of the order k_{B}T, which explains why the quantum-well heat engine has an efficiency comparable to that of a quantum-dot heat engine with level width k_{B}T.

Discussion of an Asymmetric System, a≠0

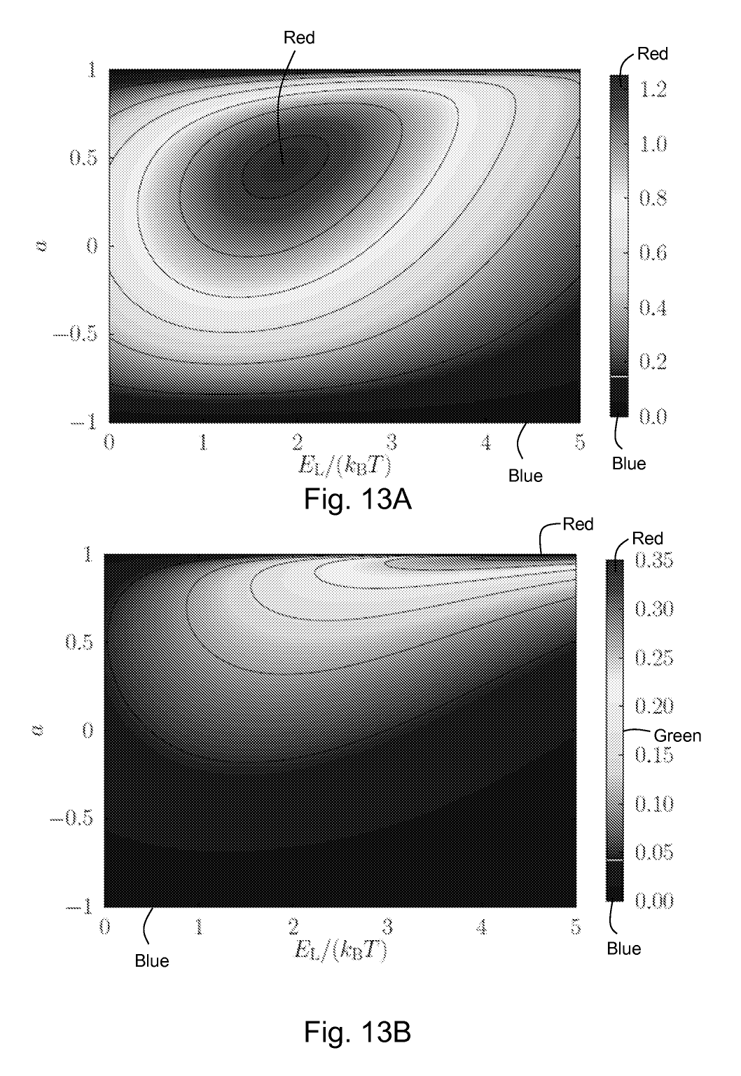

In the case of an asymmetric system, where a≠0, both the output power and the efficiency are no longer invariant under an exchange of the two level positions. Instead, power and efficiency are strongly reduced for E_{L}<0 and E_{R}>0 if a>0 (for a<0, the roles of E_{L} and E_{R} are interchanged). In contrast, for E_{L}>0 and E_{R}<0, power and efficiency are even slightly enhanced compared to the symmetric system. To determine the combination of level positions and coupling asymmetry that yields the largest output power, power was plotted as a function of the asymmetry a and the level position E_{L} (FIGS. 13A-13B). It was found that the maximal power occurs for a≈0.46 and E_{L}≈2k_{B}T while −E_{R}>>k_{B}T. The resulting power is about 20% larger than for the symmetric setup. At the same time, the efficiency at maximum power is also increased compared to the symmetric system to η≈0.12η_{C}, i.e., it is nearly doubled. It is noted that the maximal efficiency that can be obtained for the asymmetric system is given by η≈0.3η_{C}. However, similar to the symmetric setup, this occurs in a regime where the output power is highly suppressed.

Estimating the output power using the exemplary realistic device parameters of m_{eff}=0.067mₑ, T=300 K and Γ_{L}=Γ_{R}=k_{B}T, a maximum power Pₘₐₓ=0.18 W/cm² is obtained for a temperature difference ΔT=1 K. Hence, the quantum-well heat engine is nearly twice as powerful as a heat engine based on resonant-tunneling quantum dots. The output power scales with the effective mass, so that for m*=mₑ, the estimated power increases by 20 times. In addition, the quantum-well heat engine offers the advantages of being potentially easier to fabricate. As typical level splittings in quantum wells are in the range of 200-500 meV, narrow quantum wells may also be useful for room-temperature applications (though leakage phonon heat currents become of relevance then). Finally, it is noted that the device is robust with respect to fluctuations in the device properties. For the configuration discussed above, fluctuations of E_{R} do not have any effect as long as −E_{R}>>k_{B}T. Fluctuations of E_{L} by as much as k_{B}T reduce the output power by about 20% as can be seen in FIGS. 13A-13B. Hence, the disclosed device is robust with respect to fluctuations similarly to a quantum-dot based setup.

Nonlinear-Response Regime

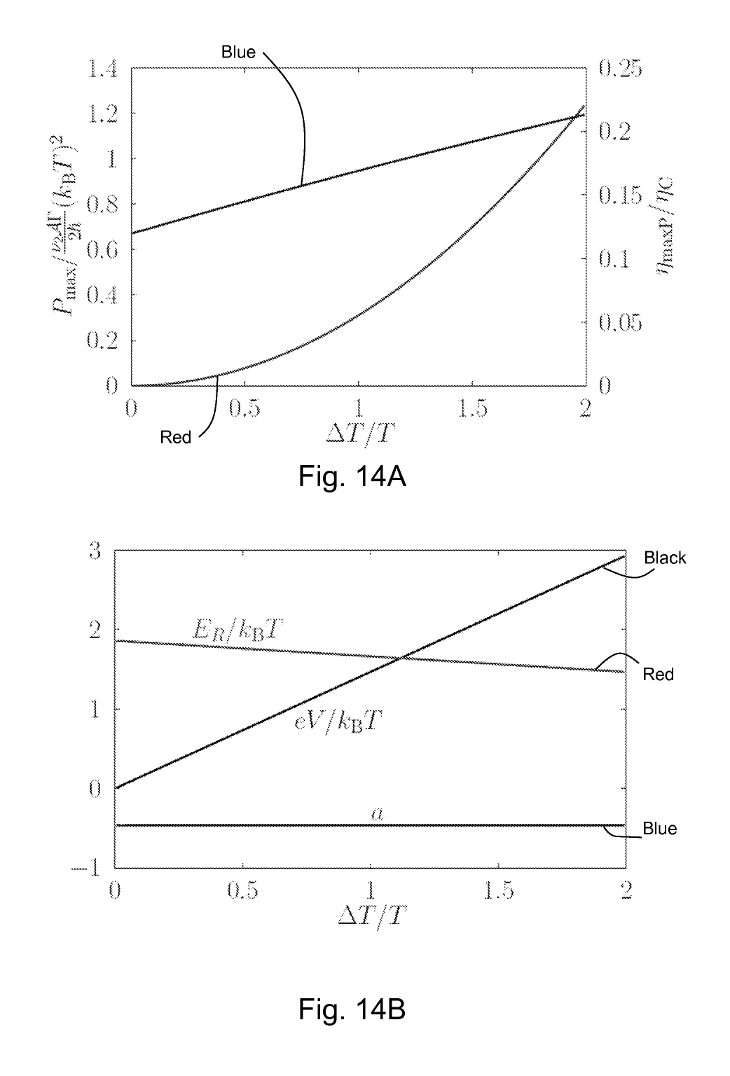

Nonlinear thermoelectrics has recently received an increasing interest. The bias voltage V, asymmetry of couplings a, and the level positions E_{L,R} were numerically optimized in order to maximize the output power. The resulting optimized parameters are shown in FIGS. 14A and 14B as a function of the temperature difference ΔT. While the optimal asymmetry a≈0.46 is independent of ΔT, the optimal bias voltage grows linear in ΔT. The right level position E_{R} decreases only slightly upon increasing ΔT. The left level position should be chosen as −E_{L}>>k_{B}T, independent of ΔT. It is not shown in FIG. 14B as the exemplary numerical optimization procedure results in large negative values for E_{L} that vary randomly from data point to data point because the dependence of the power on E_{L} is only very weak in this parameter regime.

The resulting maximal power grows quadratically in the temperature difference. It is approximately given by

$${P}_{max} = 0.3 \frac{{v}_{2} 𝒜 Γ}{2 ℏ} {( {k}_{B} Δ T )}^{2} ,$$

independent of T. Interestingly, for a given value of ΔT, the same output power is obtained in both the linear and the nonlinear regime. However, as the efficiency at maximum power grows linearly with the temperature difference, it may be preferable to operate the device as much in the nonlinear regime as possible. In the extreme limit ΔT/T=2, the quantum-well heat engine reaches η_{maxP}=0.22η_{C}, i.e., it is as efficient as a heat engine based on resonant-tunneling quantum dots while delivering more power. It is noted that the efficiency at maximum power is below the upper bound η_{C}/(2−η_{C}) previously shown in the art.

Although the present disclosure has been described with respect to one or more particular embodiments, it will be understood that other embodiments of the present disclosure may be made without departing from the spirit and scope of the present disclosure. Hence, the present disclosure is deemed limited only by the appended claims and the reasonable interpretation thereof.

What we claim is:

1. An energy-harvesting device, comprising:
a first electron reservoir having a chemical potential (μ_{L}) and a temperature (T_{Res1});
a second electron reservoir having a chemical potential (μ_{R}) and a temperature (T_{Res2}), the second electron reservoir being in spaced apart relation with the first electron reservoir;
a cavity having a chemical potential (μ_{Cav}) and a temperature (T_{Cav}) which is greater than temperatures (T_{Res1},T_{Res2}) of the first and second electron reservoirs;
a first quantum confinement structure having an operative energy (E_{L}), the first quantum confinement structure electrically connecting the first electron reservoir to the cavity; and
a second quantum confinement structure having an operative energy (E_{R}) which is different than E_{L}, the second quantum confinement structure electrically connecting the second electron reservoir to the cavity.

2. The device of claim 1, wherein a bias voltage V is applied between the first electron reservoir and the second electron reservoir such that eV=μ_{L}/μ_{R}.

3. The device of claims 1 to 2, further comprising a gate for applying a gate voltage, wherein the operative energy of the first quantum confinement structure and/or the second quantum confinement structure can be altered by providing a gate voltage at the gate.

4. The device of claims 1 to 3, further comprising:
a third electron reservoir having a chemical potential (μ₃) and a temperature (T_{Res3}), the third electron reservoir being in spaced apart relation with the second electron reservoir;
a second cavity having a chemical potential (μ_{Cav2}) and a temperature (T_{Cav2}) which is greater than temperatures (T_{Res2},T_{Res3}) of the second and third electron reservoirs; and
a third quantum confinement structure having an operative energy (E_{L1}), the third quantum confinement structure electrically connecting the second electron reservoir to the second cavity; and
a fourth quantum confinement structure having an operative energy (E_{R1}) which is different than E_{L1}, the fourth quantum confinement structure electrically connecting the third electron reservoir to the second cavity.

5. The device of claim 4, wherein E_{L}=E_{L1} and/or E_{R}=E_{R1}.

6. The device of claims 4 to 5, wherein μ_{Cav2}=μ_{Cav}.

7. The device of claims 1 to 6, wherein the first quantum confinement structure and the second quantum confinement structure are quantum dots, and the operative energy of each of the first and second quantum dots is a resonant level.

8. The device of claim 7, wherein the relationship of the cavity chemical potential and the resonant levels of the first and second quantum dots is such that: μ_{Cav}=(E_{L}+E_{R})/2.

9. The device of claims 7 to 8, wherein the difference (ΔE) between the second resonant level and the first resonant level is related to an average temperature (T=(T_{Cav}+T_{Res1}+T_{Res2})/3) of the device such that: ΔE≅6k_{B}T, where k_{B} is the Boltzmann constant.

10. The device of claims 7 to 9, wherein the resonant widths (γ) are approximately equal to k_{B}T.

11. The device of claims 7 to 10, wherein μ_{L}=/2+(E_{L}+E_{R})/2 and μ_{R}=μ/2+(E_{L}+E_{R})/2.

12. The device of claims 7 to 11, having more than one first quantum dots connecting the first electron reservoir to the cavity and more than one second quantum dots connecting the second electron reservoir to the cavity.

13. The device of claim 12, wherein the resonant levels of the more than one first quantum dots are within the range of ±10% of E_{L} and the resonant levels of each of the more than one second quantum dots is with ±10% of E_{R}.

14. The device of claims 1 to 6, wherein the first quantum confinement structure and the second quantum confinement structure are quantum wells, and the operative energy of each of the first and second quantum wells is a threshold energy.

15. The device of claim 14, wherein the first and second quantum wells are intrinsically symmetric.

16. The device of claim 15, wherein the coupling strength of the first quantum well (Γ₁) is approximately equal to the coupling strength of the second quantum well (Γ₂).

17. The device of claims 14 to 16, wherein E_{R} is substantially equal to 1.5 times a thermal energy (k_{B}T), where T is a design temperature.

18. The device of claim 14, wherein the coupling strength of the first quantum well (Γ₁) is not equal to the coupling strength of the second quantum well (Γ₂).

19. The device of claim 14 or 18, wherein Γ₁≈2.70Γ₂ and E_{R} is substantially equal to 2 times a thermal energy (k_{B}T), where T is a design temperature.

20. A method of harvesting energy from a substrate having an elevated temperature, the method comprising the steps of:
providing an energy harvesting device as defined in claims 1 to 5, having:
a first electron reservoir;
a second electron reservoir, the second electron reservoir being in spaced apart relation with the first electron reservoir;
a cavity thermally coupled to the substrate, the cavity having a chemical potential (μ_{Cav}) and a temperature (T_{Cav}) which is greater than temperatures of the first and second electron reservoirs;
a first quantum confinement structure having an operative energy (E_{L}), the first quantum confinement structure electrically connecting the first electron reservoir to the cavity;
a second quantum confinement structure having an operative energy (E_{R}) which is different than E_{L}, the second quantum confinement structure electrically connecting the second electron reservoir to the cavity; and
electrically connecting a load between the first and second electron reservoirs.

21. The method of claim 20, further comprising the step of applying a bias voltage (V) across the first and second electron reservoirs such that eV=μ_{L}−μ_{R}.

22. The method of claim 21, wherein V=Vₛₜₒₚ/2, where Vₛₜₒₚ is the voltage at which a heat-driven current flowing in a first direction is exactly compensated by a bias-driven current flowing in a second direction opposite to the first direction.

23. The method of claims 20 to 22, further comprising the step of applying a gate voltage using a gate.

24. A method of manufacturing an energy harvesting device as defined in claims 1 to 5, comprising the steps of:
providing a first electrode layer;
depositing a first quantum confinement layer on the first electrode layer, at least a portion of the first quantum confinement layer being in electrical communication with the first electrode layer and having a first operative energy (E_{L});
depositing a central layer onto the first quantum confinement layer, the central layer being in electrical communication with at least a portion of the first quantum confinement layer;
depositing a second quantum confinement layer on the central layer, at least a portion of the second quantum confinement layer being in electrical communication with the central layer and having a second operative energy (E_{R}) that is different than E_{L}; and
depositing a second electrode layer onto the second quantum confinement layer, the second electrode layer being in electrical communication with at least a portion of the second quantum confinement layer.

25. The method of claim 24, wherein step of depositing a first quantum confinement layer on the first electrode layer comprises the sub-step of:
fabricating a first quantum dot layer on the first electrode layer, the first quantum dot layer comprising a plurality of quantum dots disposed in an insulating material such that the plurality of quantum dots are not in electrical contact with each other, each quantum dot being in electrical communication with the first electrode layer and having an operative level which is substantially equal to a first resonant level (E_{L}).

26. The method of claim 25, wherein the resonant level of each quantum dot of the first quantum dot layer is ±10% of E_{L}.

27. The method of claims 24 to 26, wherein step of depositing a second quantum confinement layer on the central layer comprises the sub-step of:
fabricating a second quantum dot layer on the central layer, the second quantum dot layer comprising a plurality of quantum dots disposed in an insulating material such that the plurality of quantum dots are not in electrical contact with each other, each quantum dot being in electrical communication with the central layer and having an operative level which is substantially equal to a second resonant level (E_{R}), and wherein E_{R} is greater than an operative energy of the first quantum confinement layer.

28. The method of claim 27, wherein the resonant level of each quantum dot of the second quantum dot layer is ±10% of E_{R}.

29. The method of claims 24 to 28, wherein the relationship chemical potential (μ_{Cav}) of the central layer is selected such that: μ_{Cav}=(E_{L}+E_{R})/2.

30. The method of claim 24 or 29, wherein the first and/or second quantum confinement layer is a quantum well.
